(19) United States
(12) Patent Application Publication
(10) Pub. No.: US 2010/0302734 A1
(43) Pub. Date: Dec. 2, 2010

(54) HEATSINK AND METHOD OF FABRICATING SAME

(75) Inventors: Richard Alfred Beaupre, Pittsfield, MA (US); Ljubisa Dragoljub Stevanovic, Clifton Park, NY (US); Dieter Gerhard Brunner, Bayreuth (DE)

Correspondence Address: GENERAL ELECTRIC COMPANY;GLOBAL RESEARCH, ONE RESEARCH CIRCLE, BLDG. K1-3A59, NISKAYUNA, NY, 12309, US

(73) Assignee: GENERAL ELECTRIC COMPANY, SCHENECTADY, NY (US)

(21) Appl. No.: 12/474,333

(22) Filed: May 29, 2009

(51) Int. Cl. H05K 7/20

(52) U.S. Cl. 361/700; 361/699

(57) ABSTRACT

A heatsink assembly for cooling a heated device includes a ceramic substrate having a plurality of cooling fluid channels integrated therein. The ceramic substrate includes a topside surface and a bottomside surface. A layer of electrically conducting material is bonded or brazed to only one of the topside and bottomside surfaces of the ceramic substrate. The electrically conducting material and the ceramic substrate have substantially identical coefficients of thermal expansion.

### BACKGROUND

This invention relates generally to semiconductor power modules, more particularly, to a heatsink and method of fabricating the heatsink in ceramic substrates commonly used for electrical isolation in semiconductor power modules.

The development of higher-density power electronics has made it increasingly more difficult to cool power semiconductor devices. With modern silicon-based power devices capable of dissipating up to 500 W/cm², there is a need for improved thermal management solutions. When device temperatures are limited to 50 K increases, natural and forced air cooling schemes can only handle heat fluxes up to about one (1) W/cm². Conventional liquid cooling plates can achieve heat fluxes on the order of twenty (20) W/cm². Heat pipes, impingement sprays, and liquid boiling are capable of larger heat fluxes, but these techniques can lead to manufacturing difficulties and high cost.

An additional problem encountered in conventional cooling of high heat flux power devices is non-uniform temperature distribution across the heated surface. This is due to the non-uniform cooling channel structure, as well as the temperature rise of the cooling fluid as it flows through long channels parallel to the heated surface.

One promising technology for high performance thermal management is micro-channel cooling. In the 1980's, it was demonstrated as an effective means of cooling silicon integrated circuits, with designs demonstrating heat fluxes of up to 1000 W/cm² and surface temperature rises below 100° C. Known micro-channel designs require soldering a substrate (with micro-channels fabricated in the bottom copper layer) to a metal-composite heat sink that incorporates a manifold to distribute cooling fluid to the micro-channels. These known micro-channel designs employ very complicated backside micro-channel structures and heat sinks that are extremely complicated to build and therefore very costly to manufacture.

Some power electronics packaging techniques have also incorporated milli-channel technologies in substrates and heatsinks. These milli-channel techniques generally use direct bond copper (DBC) or active metal braze (AMB) substrates to improve thermal performance in power modules.

The foregoing substrates generally comprise a layer of ceramic (Si₃N₄, AlN, Al₂O₃, BeO, etc.) with copper directly bonded or brazed to both top and bottom of the ceramic. Due to the thermal expansion difference between the copper and ceramic, top and bottom copper are required to keep the entire assembly planar as the assembly is exposed to variations in temperature during processing and in-use conditions.

It would be desirable for reasons including, without limitation, improved reliability, reduced cost, reduced size, and greater ease of manufacture, to provide a power module heatsink having a lower thermal resistance between a semiconductor junction and the ultimate heatsink (fluid) than that achievable using known power module heatsink structures.

### BRIEF DESCRIPTION

Briefly, in accordance with one embodiment, a heat sink assembly for cooling a heated device comprises:

a layer of electrically isolating material comprising cooling fluid channels integrated therein, the layer of electrically isolating material comprising a topside surface and a bottomside surface; and

a layer of electrically conducting material bonded or brazed to only one of the topside and bottomside surfaces of the ceramic layer to form a two-layer substrate.

According to another embodiment, a heatsink assembly for cooling a heated device comprises:

a ceramic substrate comprising a plurality of cooling fluid channels integrated therein, the ceramic substrate comprising a topside surface and a bottomside surface; and

a layer of electrically conducting material bonded or brazed to only one of the topside and bottomside surfaces of the ceramic substrate.

### DRAWINGS

These and other features, aspects, and advantages of the present invention will become better understood when the following detailed description is read with reference to the accompanying drawings in which like characters represent like parts throughout the drawings, wherein:

FIG. 1 shows a heatsink assembly for cooling a power device in side view;

FIG. 2 shows interleaved inlet and outlet manifolds within a base plate of the heatsink assembly of FIG. 1;

FIG. 3 is another view of the inlet and outlet manifolds formed in the base plate of the heat sink assembly;

FIG. 4 shows the base plate and substrate in a partially exploded view and includes a detailed view of an exemplary cooling channel arrangement;

FIG. 5 shows the base plate and substrate in another partially exploded view;

FIG. 6 depicts, in cross-sectional view, an exemplary heat sink assembly for which the cooling channels are formed in the inner surface of the substrate; and

FIG. 7 shows an exemplary single-substrate embodiment of the heat sink assembly for cooling a number of power devices.

While the above-identified drawing figures set forth alternative embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTION

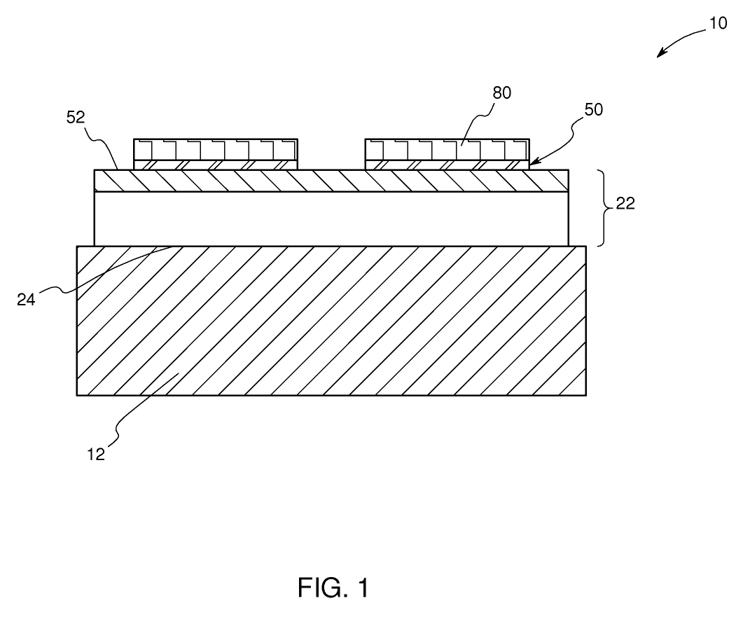

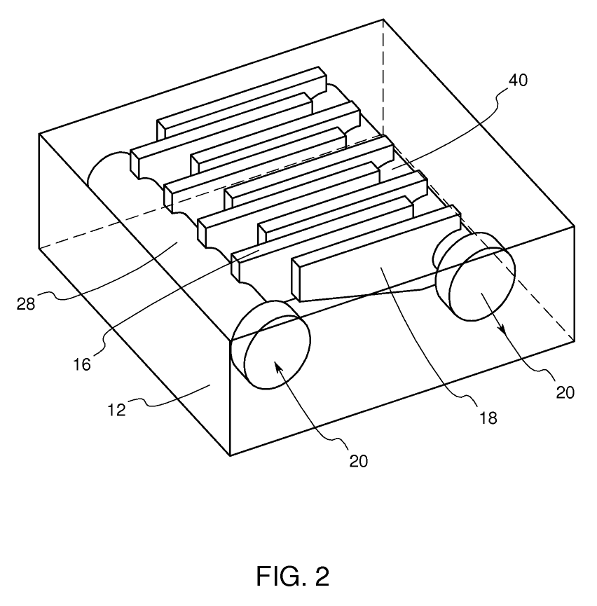

An apparatus 10 for cooling at least one heated surface 50 is described herein with reference to FIGS. 1-7. Apparatus 10, illustrated according to one embodiment in FIG. 1, includes a base plate 12, which is shown in greater detail in FIG. 2. According to one embodiment illustrated in FIG. 2, base plate 12 defines a number of inlet manifolds 16 and a number of outlet manifolds 18. The inlet manifolds 16 are configured to receive a coolant 20, and the outlet manifolds 18 are configured to exhaust the coolant. As indicated in FIG. 2, for example, inlet and outlet manifolds 16, 18 are interleaved. As indicated in FIG. 1, apparatus 10 further includes at least one substrate 22 having an inner surface 24 and an outer surface 52, the inner surface 24 being coupled to base plate 12.

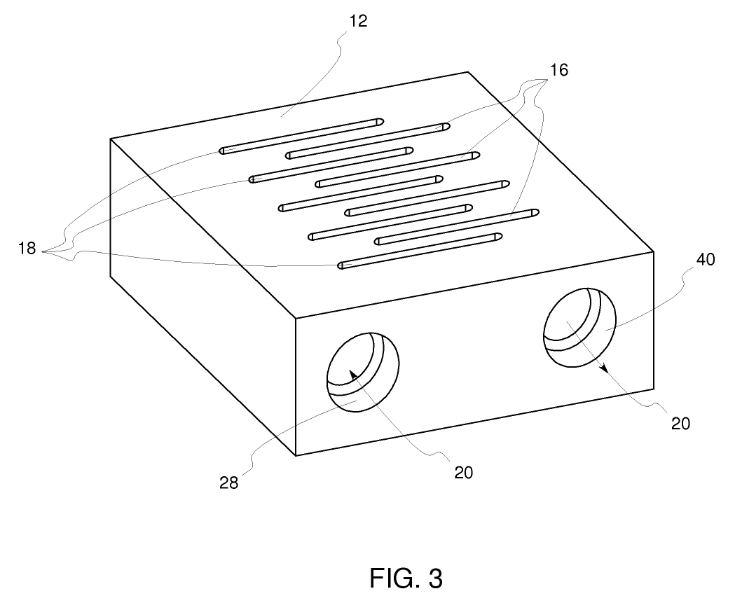

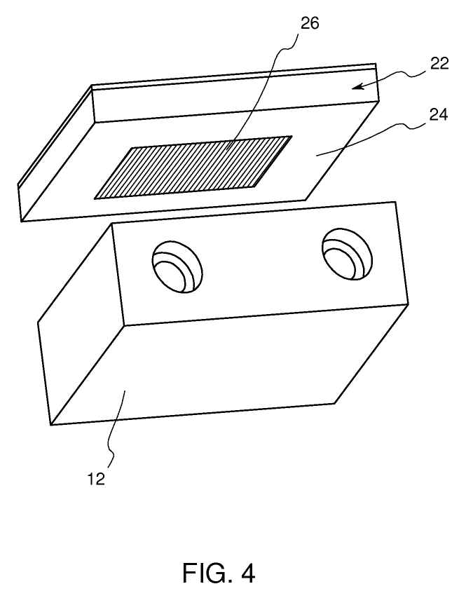

According to one embodiment as shown in FIG. 4, the inner surface 24 features a number of cooling fluid channels 26 configured to receive the coolant 20 from inlet manifolds 16 and to deliver the coolant to outlet manifolds 18. According to one aspect, cooling fluid channels 26 are oriented substantially perpendicular to inlet and outlet manifolds 16, 18. The outer surface 52 of substrate 22 is in thermal contact with the heated surface 50, as indicated in FIG. 1. Apparatus 10 further includes an inlet plenum 28 configured to supply the coolant 20 to inlet manifolds 16 and an outlet plenum 40 configured to exhaust the coolant from outlet manifolds 18. As indicated in FIGS. 2 and 3, inlet plenum 28 and outlet plenum 40 are oriented in a plane of base plate 12.

Many coolants 20 can be employed for apparatus 10, and the invention is not limited to a particular coolant. Exemplary coolants include water, ethylene-glycol, propylene-glycol, oil, aircraft fuel and combinations thereof. According to a particular embodiment, the coolant is a single phase liquid. According to another embodiment, the coolant is a multi-phase liquid. In operation, the coolant enters the manifolds 16 in base plate 12 via the input plenum 28 and flows through cooling fluid channels 26 before returning through exhaust manifolds 18 and the output plenum 40. More particularly, coolant enters inlet plenum 28, whose fluid diameter exceeds that of the other channels in apparatus 10, according to a particular embodiment, so that there is no significant pressure-drop in the plenum.

According to a particular embodiment, base plate 12 comprises a thermally conductive material. Exemplary materials include, without limitation, copper, Kovar, Molybdenum, titanium, ceramics, metal matrix composite materials and combinations thereof. According to other embodiments, base plate 12 comprises a moldable, castable or machinable material.

Cooling fluid channels 26 encompass micro-channel dimensions to milli-channel dimensions. Channels 26 may have, for example, a feature size of about 0.05 mm to about 5.0 mm according to some aspects of the invention. According to one embodiment, channels 26 are about 0.1 mm wide and are separated by a number of gaps of about 0.2 mm. According to yet another embodiment, channels 26 are about 0.3 mm wide and are separated by a number of gaps of about 0.5 mm. According to still another embodiment, channels 26 are about 0.6 mm wide and are separated by a number of gaps of about 0.8 mm. Beneficially, by densely packing narrow cooling fluid channels 26, the heat transfer surface area is increased, which improves the heat transfer from the heated surface 50.

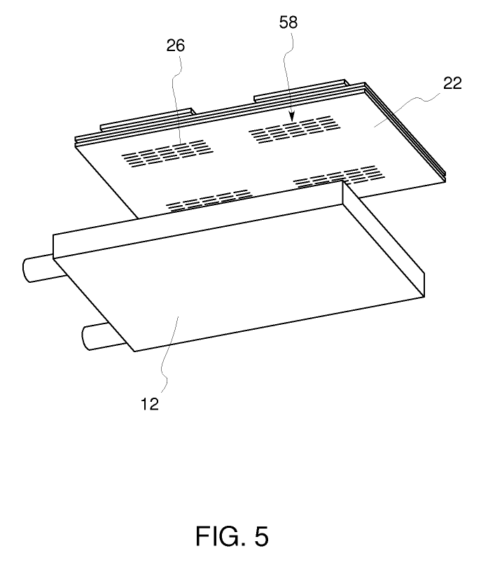

Cooling fluid channels 26 can be formed with a variety of geometries. Exemplary cooling fluid channel 26 geometries include rectilinear and curved geometries. The cooling fluid channel walls may be smooth, for example, or may be rough. Rough walls increase surface area and enhance turbulence, increasing the heat transfer in the cooling fluid channels 26. For example, the cooling fluid channels 26 may include dimples to further enhance heat transfer. In addition, cooling fluid channels 26 may be continuous, as indicated for example in FIG. 4, or cooling fluid channels 26 may form a discrete array 58, as exemplarily shown in FIG. 5. According to a specific embodiment, cooling fluid channels 26 form a discrete array 58 and are about 1 mm in length and are separated by a gap of less than about 0.5 mm.

In addition to geometry considerations, dimensional factors also affect thermal performance. According to one aspect, manifold and cooling channel geometries and dimensions are selected in combination to reduce temperature gradients and pressure drops.

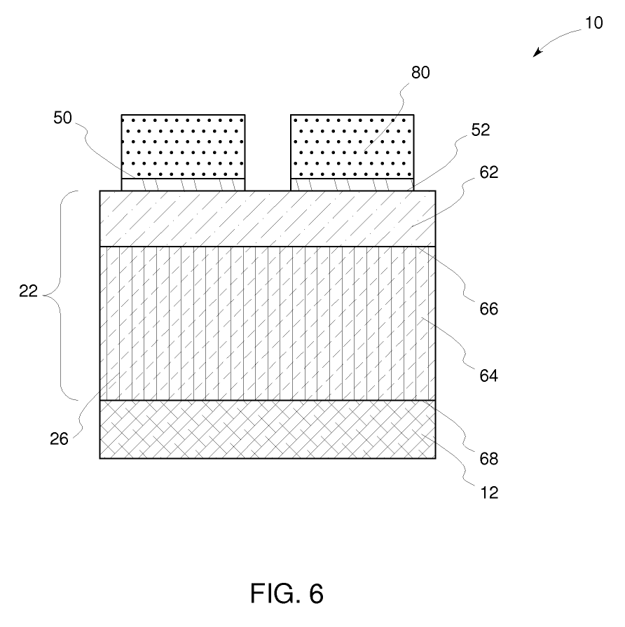

According to one embodiment shown in FIG. 6, substrate 22 includes at least one electrically conductive material 62 and at least one electrically isolating material 64 such as a suitable ceramic material. Exemplary ceramic bases include aluminum-oxide (Al₂O₃), aluminum nitride (AlN), beryllium oxide (BeO) and silicon nitride (Si₃N₄). Electrically conductive material 62 is bonded or brazed to only the topside surface 66 of the electrically isolating material 64. According to one aspect, electrically conductive material 62 comprises molybdenum, kovar, metal matrix composite or another suitable electrically conductive material that has a coefficient of thermal expansion equivalent to the electrically isolating material 64.

Since both the electrically conductive material 62 and the electrically isolating material 64 have substantially identical coefficients of thermal expansion, out of plane distortion is prevented during processing temperatures of fabricating the molybdenum or other electrically conductive material to the ceramic of other electrically isolating material 64 or other temperature variations the resultant product would be exposed to during subsequent processing or n-use conditions.

The backside surface 68 of the electrically isolating material 64, without the electrically conductive material 62, has the cooling fluid channels 26 fabricated therein. The area(s) associated with the cooling fluid channels 26 lie directly beneath the heated surface(s) 50 that are subsequently attached to the electrically conductive material 62 on the topside surface 52 of the electrically isolating material 64.

Beneficially, the completed substrate 22 can be attached to base plate 12 using any one of a number of techniques, including brazing, bonding, diffusion bonding, soldering, or pressure contact such as clamping. This provides a simple assembly process, which reduces the overall cost of the heat sink 10. Moreover, by attaching the substrate 22 to base plate 12, fluid passages are formed under the heated surfaces 50, enabling practical and cost-effective implementation of the cooling fluid channel cooling technology.

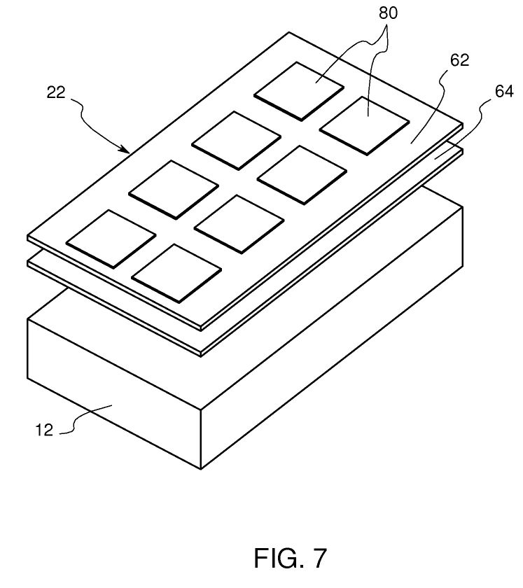

It is noted that the embodiments described herein advantageously reduce the thermal resistance between the heated surface(s) 50 and the ultimate heatsink (fluid) 20. This reduced temperature provides a more robust design of a corresponding power electronics module such as the multiple semiconductor power device 80 module depicted in FIG. 7, by reducing the maximum operating temperature and reducing the minimum to maximum temperature excursions during power cycling during device operation, thereby increasing device reliability. Further, the embodiments described herein advantageously place the cooling media 20 closer to the heated surface(s) 50 by locating the cooling fluid channels 26 in the electrically isolating material 64, thereby reducing the thermal resistance (junction to fluid) to lower levels than that achievable using known structures that employ metal layers on both the topside and bottomside surfaces of the substrate.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A heatsink assembly for cooling a heated device comprising:
a layer of electrically isolating material comprising cooling fluid channels integrated therein, the layer of electrically isolating material comprising a topside surface and a bottomside surface; and
a layer of electrically conducting material bonded or brazed to only one of the topside and bottomside surfaces of the ceramic layer to form a two-layer substrate.

2. The heatsink assembly according to claim 1, further comprising a base plate brazed or bonded to a surface of the electrically isolating layer opposite the only one surface of the electrically isolating layer bonded or brazed to the electrically conducting layer, the base plate comprising a manifold array configured to deliver cooling fluid to the electrically isolating layer cooling fluid channels and to receive cooling fluid expelled from the electrically isolating layer cooling fluid channels.

3. The heatsink assembly according to claim 2, wherein the cooling fluid comprises a single phase or multi-phase liquid.

4. The heatsink assembly according to claim 2, wherein the base plate comprises a moldable, castable or machinable material.

5. The heatsink assembly according to claim 2, wherein the substrate and base plate together provide a smaller thermal resistance between the junction of a semiconductor device mounted to the substrate and the cooling fluid than that achievable with a substrate comprising both a metal layer brazed or bonded to both top and bottom surfaces of the substrate and a corresponding base plate.

6. The heatsink assembly according to claim 2, wherein the manifold array comprises a plurality of inlet manifolds and a plurality of outlet manifolds, the inlet and outlet manifolds interleaved and oriented in a plane of the base plate.

7. The heatsink assembly according to claim 2, wherein the cooling fluid channels are oriented substantially perpendicular to the inlet and outlet manifolds.

8. The heatsink assembly according to claim 2, wherein the cooling fluid is selected from water, ethylene-glycol, propylene-glycol, oil, aircraft fuel and combinations thereof.

9. The heatsink assembly according to claim 1, wherein the electrically isolating layer comprises ceramic.

10. The heatsink assembly according to claim 9, wherein the electrically isolating layer comprises aluminum oxide (Al₂O₃), aluminum nitride (AlN), beryllium oxide (BeO) and silicon nitride (Si₃N₄).

11. The heatsink assembly according to claim 1, wherein the electrically conducting layer comprises a coefficient of thermal expansion substantially identical to that of the electrically isolating layer.

12. The heatsink assembly according to claim 11, wherein the electrically conducting layer comprises molybdenum, kovar, or metal matrix composite material.

13. The heatsink assembly according to claim 1, wherein the electrically isolating layer and the electrically conducting layer together have a coefficient of thermal expansion preventing out of plane distortion during processing or in-use conditions.

14. The heatsink assembly according to claim 1, wherein the cooling channels comprise micro-channel dimensions to milli-channel dimensions.

15. The heatsink assembly according to claim 1, wherein the cooling fluid channels are configured to lie directly beneath semiconductor devices attached to the electrically conducting layer.

16. The heatsink assembly according to claim 1, further comprising at least one semiconductor power device thermally coupled to one or more cooling fluid channels via the electrically conducting layer.

17. A heatsink assembly for cooling a heated device comprising:
a ceramic substrate comprising a plurality of cooling fluid channels integrated therein, the ceramic substrate comprising a topside surface and a bottomside surface; and
a layer of electrically conducting material bonded or brazed to only one of the topside and bottomside surfaces of the ceramic substrate.

18. The heatsink assembly according to claim 17, wherein the ceramic substrate comprises aluminum oxide (Al₂O₃), aluminum nitride (AlN), beryllium oxide (BeO) and silicon nitride (Si₃N₄).

19. The heatsink assembly according to claim 17, wherein the electrically conducting layer comprises a coefficient of thermal expansion substantially identical to that of the ceramic substrate.

20. The heatsink assembly according to claim 19, wherein the electrically conducting layer comprises molybdenum, kovar, or metal matrix composite material.

21. The heatsink assembly according to claim 17, wherein the cooling channels comprise micro-channel dimensions to milli-channel dimensions.
